(19) United States
(12) Patent Application Publication
(10) Pub. No.: US 2013/0217225 A1
(43) Pub. Date: Aug. 22, 2013

(54) METHOD FOR MANUFACTURING SEMICONDUCTOR DEVICE

(71) Applicants: Takashi Hayakawa, Minato-ku (JP); Kenichi Hara, Nirasaki City (JP); Takashi Tanaka, Nirasaki City (JP)

(72) Inventors: Takashi Hayakawa, Minato-ku (JP); Kenichi Hara, Nirasaki City (JP); Takashi Tanaka, Nirasaki City (JP)

(73) Assignee: TOKYO ELECTRON LIMITED, Tokyo (JP)

(21) Appl. No.: 13/819,431

(22) PCT Filed: Jul. 29, 2011
(86) PCT No.: PCT/JP2011/067400

§ 371 Date: Mar. 27, 2013

(30) Foreign Application Priority Data
Aug. 31, 2010 (JP) 2010-193985
Aug. 31, 2010 (JP) 2010-193986

(51) Int. Cl. H01L 21/306

(52) U.S. Cl. CPC H01L 21/30604
USPC 438/643

(57) ABSTRACT

A method comprising the steps of: forming a copper film (101) on a Cu barrier film (100); forming a mask material (102) on the copper film (101); anisotropically etching the copper film (101) until the Cu barrier film (100) is exposed, using the mask material (102) as a mask; and removing the mask material (102) and subsequently forming a plating film (104) that contains a substance for suppressing copper diffusion on the anisotropically etched copper film (101), using an electroless plating method that utilizes a selective deposition in which catalytic action occurs with respect to the copper film (101) but not the Cu barrier film (100).

### TECHNICAL FIELD

The present invention relates to a method for manufacturing a semiconductor device.

### BACKGROUND

A high speed operation of semiconductor devices such as semiconductor integrated circuit devices has recently been progressed. The high speed of operation has been realized by, for example, lowering the resistance of a wiring material. For that reason, instead of aluminum that has been used conventionally, copper having a low resistance than aluminum has been used for the wiring materials.

However, it is difficult to apply the existing dry etching technologies to process copper. This is because that the compound of copper formed while copper is being etched generally has a relatively lower vapor pressure to be evaporated. For example, technologies such as an Ar sputtering and a Cl gas RIE have been attempted, but these technologies were not able to be put to practical use due to the problem such as, for example, the attachment of copper to an inner wall of a chamber. For that reason, copper-based wiring is formed only using a damascene technology. The damascene technology is a technology that forms a trench along a wiring pattern in advance in an interlayer dielectric film, forms a thin copper film to fill the trench, and chemically and mechanically polishes the thin copper film using a CMP method, thereby remaining the copper only inside the trench.

However, in the damascene technology, the trench is formed in an interlayer dielectric film. For this reason, process that increases the relative dielectric constant of the interlayer dielectric film, such as forming of a trench, ashing a mask material used in the forming of the trench, and cleaning after the ashing, have to be involved.

An anisotropic dry etching method for copper, which does not depend on the damascene technology, is disclosed in Patent Document 1. The technology in Patent Document 1 forms a mask on a copper film, performs an anisotropic oxidation processing to the copper film through the mask, and etches the copper oxide by an organic acid gas.

However, copper is easily diffused into the interlayer dielectric film. For that reason, a Cu barrier film that suppresses the diffusion of the copper has to be formed prior to forming the copper film. In the damascene technology, the Cu barrier film may be simply and practically formed by forming the Cu barrier film and the copper film in this order after forming the trench in the interlayer dielectric film. However, in a case of the anisotropically etched copper film, a practical method of forming the Cu barrier film does not exist as of now as Patent Document 1 does not disclose how to form the Cu barrier film.

Meanwhile, a method called dual damascene technology is known as a type of damascene technology. The dual damascene technology concurrently forms on a single copper film a wiring pattern and a via pattern that electrically connects an upper layer wiring with a lower layer wiring. For that reason, an anisotropic etching also requires the technology that concurrently forms a wiring pattern and a via pattern.

However, the method for concurrently forming the wiring pattern and the via pattern on a single copper film using the anisotropic etching does not exist as of now as Patent Document 1 does not disclose the method.

### PRIOR ART DOCUMENT

### Patent Document

Patent Document 1: Japanese Patent Laid-Open Publication No. 2010-27788.

### DISCLOSURE OF THE INVENTION

### Problems to be Solved

An object of the present invention is to provide a semiconductor device manufacturing method capable of practically forming a Cu barrier film on an anisotropically etched copper film.

Another object of the present invention is to provide a semiconductor device manufacturing method capable of concurrently forming a wiring pattern and a via pattern on a single copper film using an anisotropic etching.

### Means to solve the Problem

According to a first aspect of the present invention, there is provided a semiconductor device manufacturing method including: forming a copper film on a Cu barrier film; forming a mask material on the copper film; anisotropically etching the copper film using the mask material as a mask until the Cu barrier film is exposed; and forming a plating film including a material that suppresses the diffusion of the copper on the anistropically etched copper film using an electroless plating method that uses a selective precipitation phenomenon which has a catalytic action for the copper film and does not have the catalytic action for the Cu barrier film, after removing the mask material.

According to a second aspect of the present invention, there is provided a semiconductor device manufacturing method including: forming a copper film on a Cu barrier film; forming mask materials to be spaced apart from each other on the copper film; anisotropically etching the copper film the mask materials as a mask until the Cu barrier film is exposed; and forming an interlayer dielectric film having a space between the anisotropically etched copper films by depositing an insulating material on the anisotropically etched copper film to be pinched-off on the top of the copper film after removing the mask materials.

According to a third aspect of the present invention, there is provided a semiconductor device manufacturing method including: (1) forming a copper film on a barrier film; (2) forming a first mask material on the copper film; (3) anisotropically etching the copper film using the first mask material as a mask until the barrier film is exposed; (4) forming a second mask material on the anisotropically etched copper film after removing the first mask material; (5) anisotropically etching the copper film up to the midway of the copper film using the second mask material as a mask; and (6) forming an interlayer dielectric film around the anisotropically etched copper film by depositing an insulating material on the anisotropically etched copper film after removing the second mask material.

### BRIEF DESCRIPTION OF THE DRAWINGS

FIG. 1A is a cross-sectional view illustrating a first example of a semiconductor device manufacturing method according to a first exemplary embodiment of the present invention.

FIG. 1B is a cross-sectional view illustrating the first example of the semiconductor device manufacturing method according to the first exemplary embodiment of the present invention.

FIG. 1C is a cross-sectional view illustrating the first example of the semiconductor device manufacturing method according to the first exemplary embodiment of the present invention.

FIG. 1D is a cross-sectional view illustrating the first example of the semiconductor device manufacturing method according to the first exemplary embodiment of the present invention.

FIG. 1E is a cross-sectional view illustrating the first example of the semiconductor device manufacturing method according to the first exemplary embodiment of the present invention.

FIG. 1F is a cross-sectional view illustrating the first example of the semiconductor device manufacturing method according to the first exemplary embodiment of the present invention.

FIG. 2A is a cross-sectional view illustrating a second example of the semiconductor device manufacturing method according to the first exemplary embodiment of the present invention.

FIG. 2B is a cross-sectional view illustrating the second example of the semiconductor device manufacturing method according to the first exemplary embodiment of the present invention.

FIG. 2C is a cross-sectional view illustrating the second example of the semiconductor device manufacturing method according to the first exemplary embodiment of the present invention.

FIG. 3A is a perspective view illustrating a first example of a semiconductor device manufacturing method according to a second exemplary embodiment of the present invention.

FIG. 3B is a perspective view illustrating the first example of the semiconductor device manufacturing method according to the second exemplary embodiment of the present invention.

FIG. 3C is a perspective view illustrating the first example of the semiconductor device manufacturing method according to the second exemplary embodiment of the present invention.

FIG. 3D is a perspective view illustrating the first example of the semiconductor device manufacturing method according to the second exemplary embodiment of the present invention.

FIG. 3E is a perspective view illustrating the first example of the semiconductor device manufacturing method according to the second exemplary embodiment of the present invention.

FIG. 3F is a perspective view illustrating the first example of the semiconductor device manufacturing method according to the second exemplary embodiment of the present invention.

FIG. 3G is a perspective view illustrating the first example of the semiconductor device manufacturing method according to the second exemplary embodiment of the present invention.

FIG. 3H is a perspective view illustrating the first example of the semiconductor device manufacturing method according to the second exemplary embodiment of the present invention.

FIG. 3I is a perspective view illustrating the first example of the semiconductor device manufacturing method according to the second exemplary embodiment of the present invention.

FIG. 3J is a perspective view illustrating the first example of the semiconductor device manufacturing method according to the second exemplary embodiment of the present invention.

FIG. 3K is a perspective view illustrating the first example of the semiconductor device manufacturing method according to the second exemplary embodiment of the present invention.

FIG. 3L is a perspective view illustrating the first example of the semiconductor device manufacturing method according to the second exemplary embodiment of the present invention.

FIG. 4A is a perspective view illustrating a second example of the semiconductor device manufacturing method according to the second exemplary embodiment of the present invention.

FIG. 4B is a perspective view illustrating the second example of the semiconductor device manufacturing method according to the second exemplary embodiment of the present invention.

FIG. 4C is a perspective view illustrating the second example of the semiconductor device manufacturing method according to the second exemplary embodiment of the present invention.

FIG. 4D is a perspective view illustrating the second example of the semiconductor device manufacturing method according to the second exemplary embodiment of the present invention.

FIG. 4E is a perspective view illustrating the second example of the semiconductor device manufacturing method according to the second exemplary embodiment of the present invention.

FIG. 5A is a perspective view illustrating a third example of the semiconductor device manufacturing method according to the second exemplary embodiment of the present invention.

FIG. 5B is a perspective view illustrating the third example of the semiconductor device manufacturing method according to the second exemplary embodiment of the present invention.

FIG. 5C is a perspective view illustrating the third example of the semiconductor device manufacturing method according to the second exemplary embodiment of the present invention.

### DETAILED DESCRIPTION TO EXECUTE THE INVENTION

Hereinafter, exemplary embodiments of the present invention will be described with reference to the accompanying drawings. Further, common parts are referred to as common reference numerals in each of the exemplary embodiments.

### First Exemplary Embodiment

(First Example)

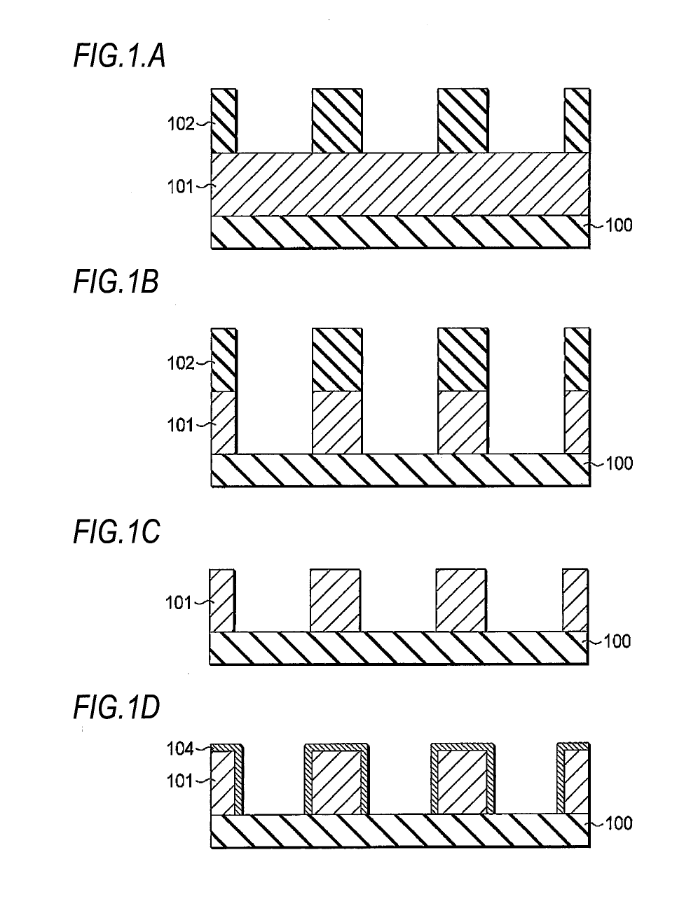

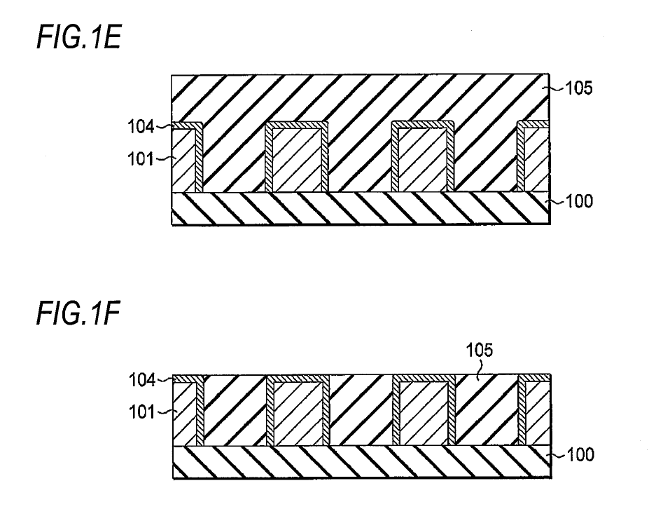

FIGS. 1A to 1F are cross-sectional views illustrating a first example of a semiconductor device manufacturing method according to a first exemplary embodiment of the present invention.

As illustrated in FIG. 1A, a copper (Cu) film 101 is formed on a substantially flat Cu barrier film 100 formed on a semiconductor wafer (not illustrated). An example of Cu barrier film 100 is a SiCN film. Cu barrier film 100 may be any film that may suppress the diffusion of copper and may be, for example, a SiC film. The film forming method may be a method capable of obtaining a required film thickness, and may be a method that forms a dense copper film. As a film forming method as described above, for example, a method that combines a PVD film forming of copper and an electro-plating of copper, and a method that combines a PVD film forming and a CVD film forming may be considered. Next, a plurality of mask materials 102 are formed, which are disposed to be spaced apart from each other on copper film 101. The method of forming mask materials 102 may be a photolithography method because the method may form a fine pattern.

Next, as illustrated in FIG. 1B, copper film 101 is anisotropically etched using mask materials 102 as a mask for an etching.

Next, mask materials 102 are removed as illustrated in FIG. 1C.

Next, as illustrated in FIG. 1D, a plating film is formed on copper film 101 using an electroless plating method that uses a selective precipitation phenomenon. In the present example, a cobalt-tungsten (CoW) film 104 is formed as the plating film. On copper film 101, the precipitation is initiated by a catalytic action to form plating film (CoW film) 104, but the plating film is not formed on Cu barrier film 100 because the catalytic action does not exist on the Cu barrier film. CoW film 104 is converted into a CoWP film when a phosphate-based reducing agent is used, and is converted into a CoWB film when a dimethylamineborane (DMAB) is used. These films were developed for the purpose of the selective precipitation on a copper film to suppress an electromigration. The cobalt itself has a lower barrier characteristic that suppresses the diffusion of the copper, but may be used as a Cu barrier film that suppresses the diffusion of the copper by being alloyed with tungsten of high concentration.

Next, as illustrated in FIG. 1E, an interlayer dielectric film 105 is formed on Cu barrier film 100 and CoW film 104. As for interlayer dielectric film 105, a film having a low dielectric constant, which is referred to as a “low-k film”, may be used to operate a semiconductor integrated circuit device in a high speed. In the present specification, the film having the low dielectric constant is defined as a film of which the relative dielectric constant is lower than that of a silicon dioxide. In the present example, as an example of interlayer dielectric film 105, a film formed using a spin coating method which is excellent in burying characteristic, for example, an organic polymer-based film having the low electric constant, is used.

Next, as illustrated in FIG. 1F, interlayer dielectric film 105 is mechanically and chemically polished using a CMP method. The end point of the mechanical and chemical polishing may be sensed by detecting a change of a current that flows through a motor of a CMP apparatus, at the time when CoW film 104 or copper film 101 is exposed. In the present example, the time when CoW film 104 is exposed is set to the end point of the mechanical and chemical polishing.

According to the first example of the first exemplary embodiment, the plating film that includes a material that suppresses the diffusion of the copper is formed in a single process on anisotropically etched copper film 101. The process uses the electroless plating method that uses the selective precipitation phenomenon which has the catalytic action for copper film 101 and does not have the catalytic action for Cu barrier film 100. In the present example, an alloy formed by making cobalt contain at least tungsten, for example, CoW film 104 is formed as the plating film in a single process. As described above, the alloy formed by making cobalt contain at least tungsten may be used for a Cu barrier film that suppresses the diffusion of copper.

Therefore, according to the first example of the first exemplary embodiment, an advantage may be obtained in that the Cu barrier film may be formed simply and practically on anisotropically etched copper film 101.

Also, according to the first example of the first exemplary embodiment, there is no process that increases the relative dielectric constant of interlayer dielectric film 105, such as, for example, forming a trench along a pattern of the inner wiring for interlayer dielectric film 105, ashing the mask material used for forming the trench, and cleaning after the ashing, which have been required in the damascene method. For that reason, a damaged layer does not occur in a portion of interlayer dielectric film 105 to be in contact with a side surface of copper film 101. Since the damaged layer does not occur in interlayer dielectric film 105, an advantage may be obtained in that the increase of the relative dielectric constant of interlayer dielectric film 105 is suppressed during the process, and the increase of wiring delay is suppressed, thereby attributing the high speed operation of semiconductor integrated circuit devices.

In addition, copper film 101 is metalized on substantially flat Cu barrier film 100. For that reason, in the first example of the first exemplary embodiment, it is not required to metalize copper film 101 in a fine trench as in the damascene method, and therefore an advantage may also be obtained in that it is more advantageous in further miniaturizing semiconductor integrated circuit devices.

Further, according to the first example of the first exemplary embodiment, a plating film that selectively suppresses the diffusion of the copper, for example, the CoW film, is formed on the surface of anisotropically etched copper film 101. For that reason, the Cu barrier film may not be formed in the trench. Because of the above reason, it is advantageous in further miniaturizing semiconductor integrated circuit devices.

(Second Example)

The second example of the first exemplary embodiment relates to a semiconductor device manufacturing method which may form an air gap structure using a less number of processes. Such an air gap structure is being developed, aiming to a semiconductor integrated circuit device having a higher operational speed.

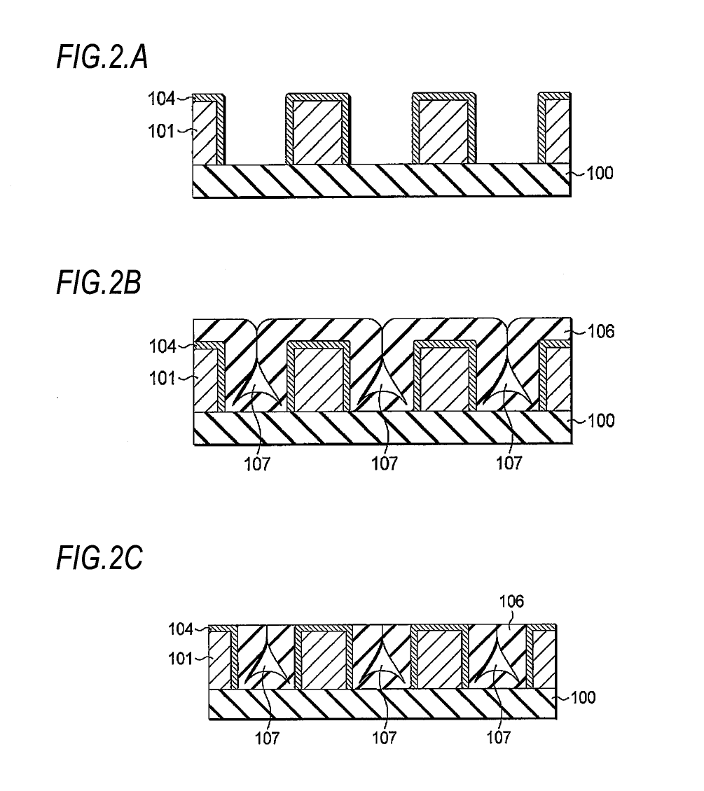

First, as illustrated in FIG. 2A, a cobalt-tungsten (CoW) film 104 is formed on a copper film 101 according to the manufacturing method described above with reference to FIGS. 1A to 1D.

Next, as illustrated in FIG. 2B, an interlayer dielectric film 106 is formed on a Cu barrier film 100 and CoW film 104. In the present example, interlayer dielectric film 106 is formed using a CVD method. Further, in the present example, a film having a low dielectric constant may also be used for interlayer dielectric film 106 for the sake of high speed of operation. An example of the dielectric film having the low electric constant capable of being formed using the CVD method is a SiOC film.

Basically, the CVD method is a conformal film forming method, but the film forming rate is higher at an entrance of a trench as compared to the bottom of the trench. For that reason, in a trench having high aspect ratio, insulating materials are pinched off, thereby being connected with each other at the entrance. As described above, on anisotropically etched copper film 101, the insulating materials may be deposited to be pinched-off on the top of copper film 101, thereby forming a space 107 within interlayer dielectric film 106. That is, an air gap may be formed. The relative dielectric constant within space 107 is 1. For this reason, an effective dielectric constant may be further lowered between copper films 101.

Next, as illustrated in FIG. 2C, interlayer dielectric film 106 is mechanically and chemically polished using the CMP method as in the first example, and the surface of interlayer dielectric film 106 retreats.

According to the second example of the first exemplary embodiment as described above, the number of the processes in forming the air gap structure may be reduced.

Specifically, for example, when a damascene method is used, an air gap structure cannot be obtained unless the following processes (1) to (5) are performed.

(1) Forming a thin film.

(2) Forming a trench in the thin film.

(3) Burying copper in the trench.

(4) Peeling the thin film.

(5) Forming an interlayer dielectric film using a CVD method.

Whereas, according to the second example of the first exemplary embodiment, since copper film 101 is directly patterned, the above processes (1) to (4) may be omitted.

That is, according to the second example of the first exemplary embodiment, the advantages as in the first example may be obtained. Further, interlayer dielectric film 106 with space 107 may be formed through the reduced number of processes by depositing the insulating material on anisotropically etched copper film 101 such that the insulating material is pinched-off on the top of copper film 101.

Accordingly, the effective dielectric constant between anisotropically etched copper films 101 may be lowered without increasing the number of processes, and thus, an advantage may be obtained in that the manufacturing time in manufacturing semiconductor integrated circuit devices may be shortened.

### Second Exemplary Embodiment

(First Example)

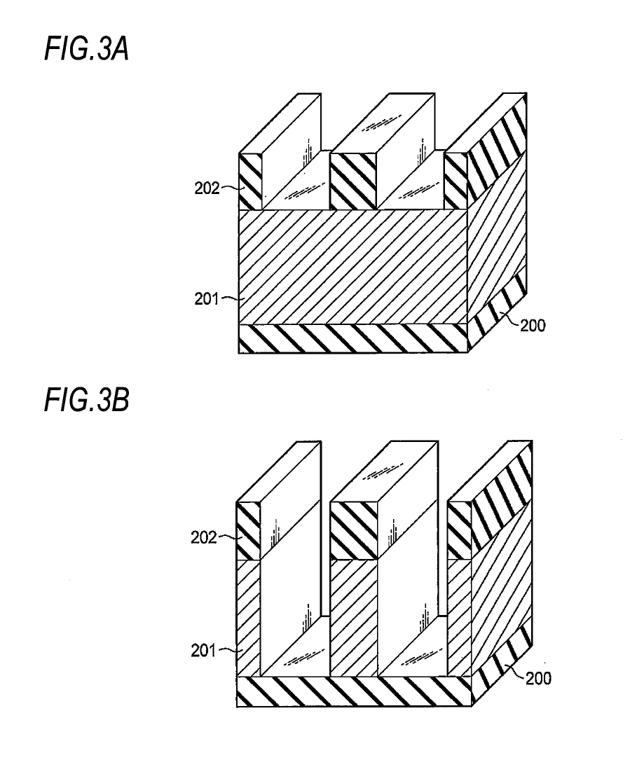

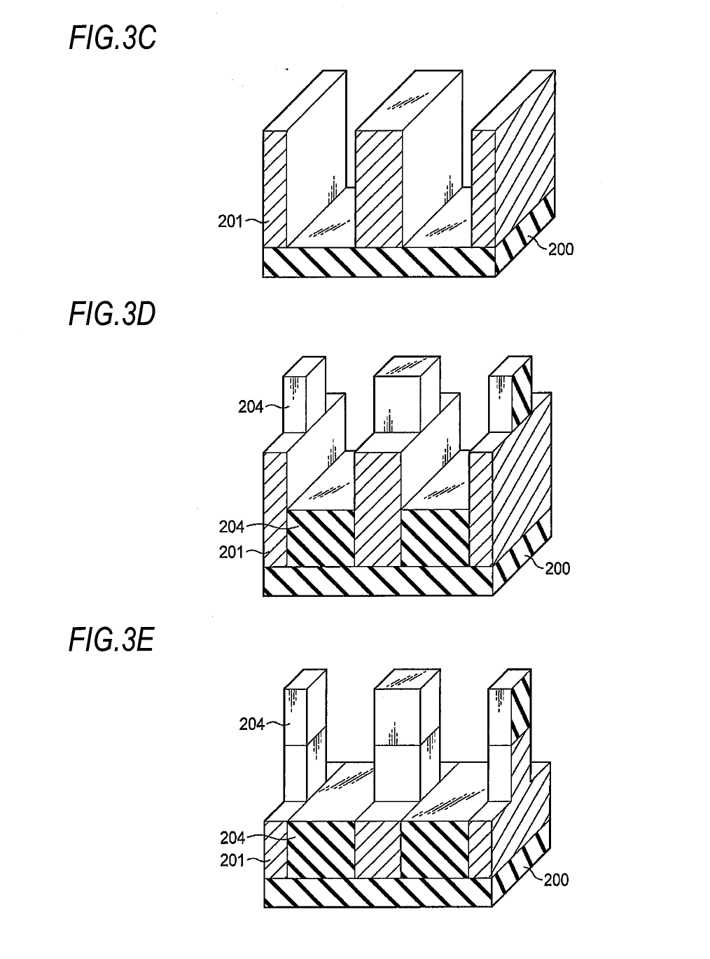

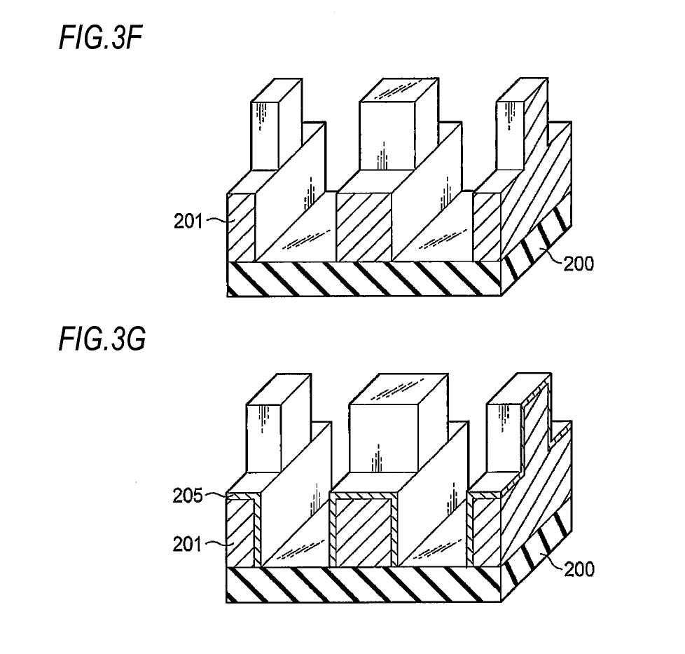

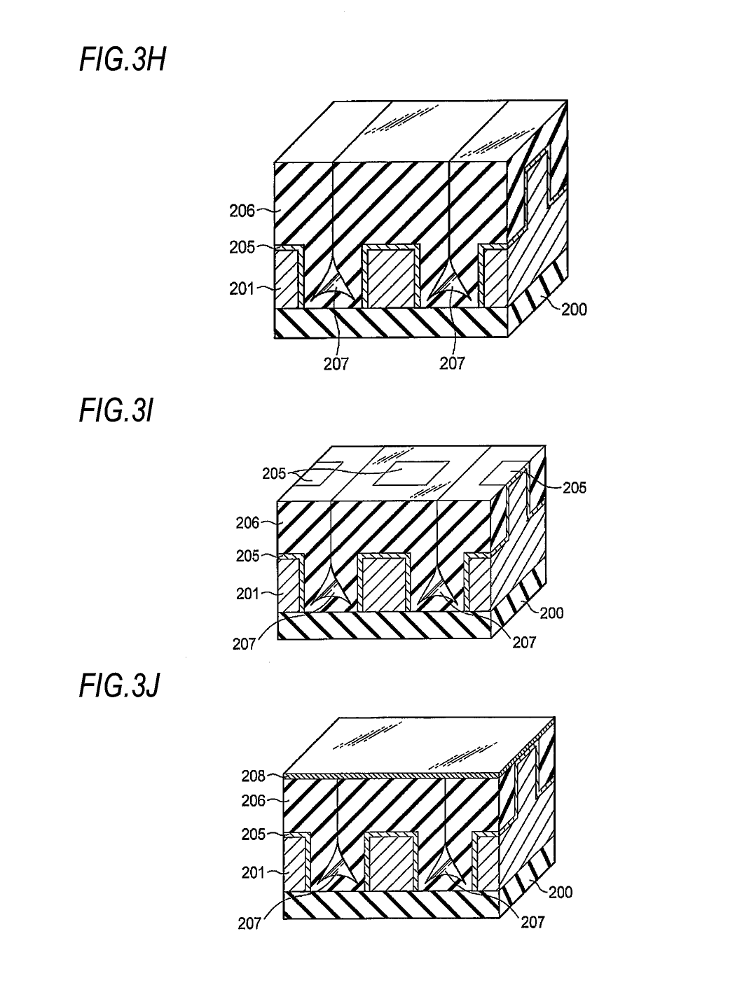

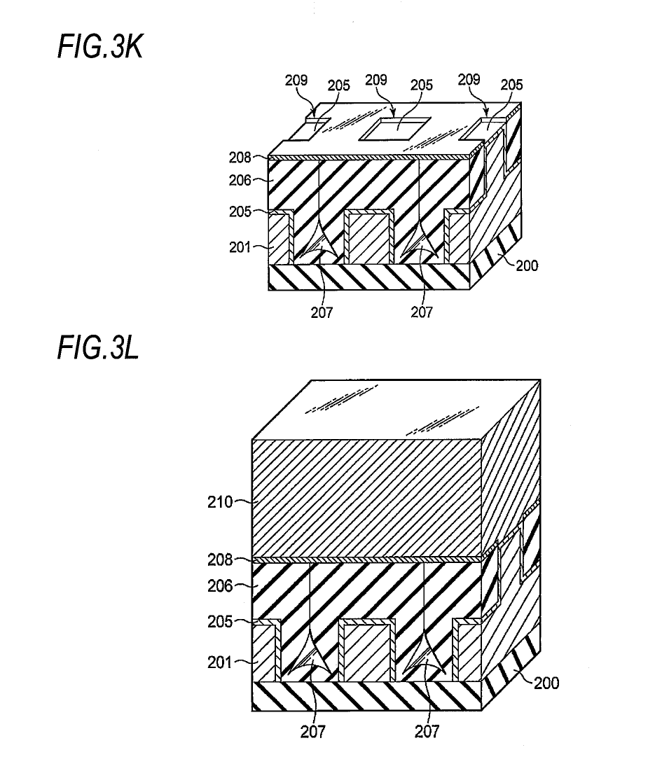

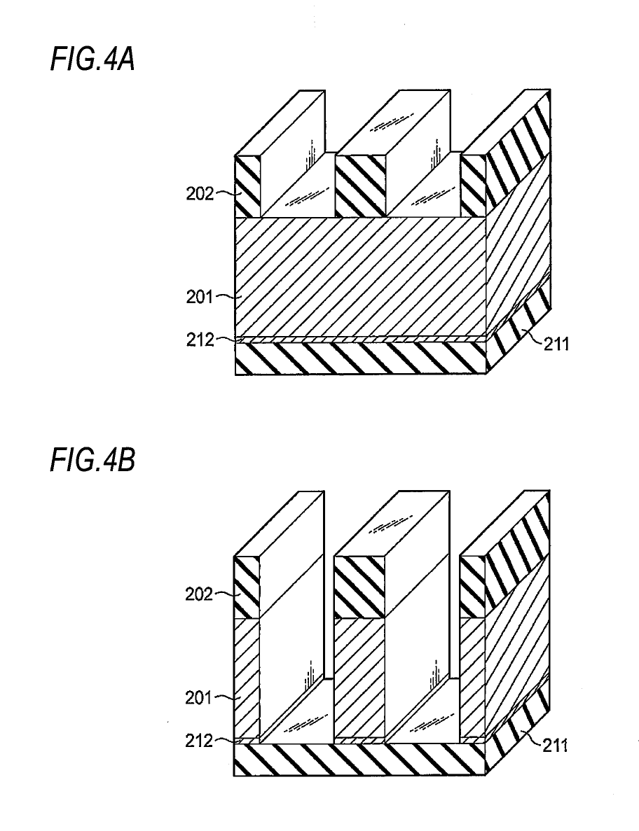

FIGS. 3A to 3L are cross-sectional views illustrating a first example of a semiconductor device manufacturing method according to a second exemplary embodiment of the present invention.

First, as illustrated in FIG. 3A, a first layered copper (Cu) film 201 is formed on a first layered Cu barrier film 200, which is substantially flat and is formed on a semiconductor wafer (not illustrated). An example of first layered barrier film 200 is a SiCN film. First layered barrier film 200 may be a film that may suppress the diffusion of a copper and may also be, for example, a SiC film. The film forming method of first layered copper film 201 is a method capable of obtaining a required film thickness, and may be a method that forms a dense copper film. As for a film forming method as described above, for example, a method that combines a PVD film forming of copper and an electrical plating of copper, and a method that combines a PVD film forming and a CVD film forming may be considered. Next, a first mask material 202 is formed on first layered copper film 201. The method of forming first mask material 202 may be a photolithography method, because the method may form a fine pattern. In the present example, the pattern of first mask material 202 corresponds to a inner wiring pattern of a semiconductor integrated circuit device.

Next, as illustrated in FIG. 3B, first layered copper film 201 is anisotropically etched using first mask material 202 as a mask for the etching. The anisotropic etching method of first layered copper film 201, which will be described later, includes: a method that irradiates oxygen ions to copper film 201 under an organic compound gas atmosphere, for example, under an organic acid gas atmosphere to anisotropically etch first layered copper film 201, and a method that irradiates oxygen ions to first layered copper film 201 to anisotropically oxidize first layered copper film 201 and removes the anisotropically oxidized portion.

Next, first mask materials 202 are removed as illustrated in FIG. 3C.

Next, as illustrated in FIG. 3D, a second mask material 204 is formed on first layered barrier film 200 and first layered copper film 201. Second mask material 204 may also be formed using the photolithography method in the viewpoint of forming a fine pattern as first mask material 202. In the present example, the pattern of second mask material 204 corresponds to a via pattern that electrically connects an upper layered wiring with a lower layered wiring.

Next, as illustrated in FIG. 3E, first layered copper film 201 is anisotropically etched up to the midway of first layered copper film 201, in the present example, until first layered copper film 201 arrives at the height of connecting part (vias) with a second layered copper film to be formed later, using second mask material 204 as a mask for the etching.

Next, second mask material 204 is removed as illustrated in FIG. 3F. Therefore, first layered copper film 201 is processed to the first layered inner wiring pattern and the via pattern.

Next, as illustrated in FIG. 3G, a cobalt-tungsten (CoW) film 205 is formed on first layered copper film 201 using an electroless plating method that uses a selective precipitation phenomenon. On first layered copper film 201, the precipitation is initiated by a catalytic action to form plating film (CoW film) 205, but the plating film is not formed on first layered barrier film 200 because that the catalytic action does not exist on the first layered barrier film. CoW film 205 is converted into a CoWP film when a phosphate reducing agent is used, and is converted into a CoWB film when a dimethylamineborane (DMAB) is used. These films were developed for the purpose of the selective precipitation on a copper film to suppress an electromigration. The cobalt itself has a lower barrier characteristic that suppresses the diffusion of the copper, but may be used as a barrier film that suppresses the diffusion of the copper by being alloyed with the tungsten of high concentration.

Next, as illustrated in FIG. 3H, an interlayer dielectric film 206 is formed on first layered barrier film 200 and CoW film 205. As for interlayer dielectric film 206, a film of a low dielectric constant, which is referred to as a “low-k film”, may be used to operate a semiconductor integrated circuit device in a high speed. In the present specification, the film of the low dielectric constant is defined as a film that has a relative dielectric constant is lower than that of a silicon dioxide. In the present example, interlayer dielectric film 206 is formed using a CVD method. An example of the film of the low dielectric constant to be formed using the CVD method is a SiOC film.

Basically, the CVD method is a conformal film forming method, but the film forming rate is higher at an entrance of a trench as compared to the bottom of the trench. For that reason, in a trench having a high aspect ratio, the insulating materials are pinched off at the entrance, thereby being connected with each other at the entrance. As described above, on anisotropically etched copper film 201, the insulating materials may be deposited to be pinched-off on the top of copper film 201, thereby forming a space 207 within interlayer dielectric film 206. That is, an air gap may be formed. The relative dielectric constant within space 207 is 1. For this reason, an effective dielectric constant may be further lowered between copper films 201.

Next, as illustrated in FIG. 31, interlayer dielectric film 106 is mechanically and chemically polished using the CMP method, and the surface of interlayer dielectric film 206 retreats. The end point of the mechanical and chemical polishing may be sensed by detecting a change of a current that flows through a motor of a CMP apparatus, at a timing when CoW film 205 or first layered copper film 201 is exposed. In the present example, the timing when CoW film 205 is exposed becomes the end point of the mechanical and chemical polishing.

Next, as illustrated in FIG. 3J, a second layered barrier film 208 that suppresses the diffusion of copper is formed on CoW film 205 and interlayer dielectric film 206. In the present example, second layered barrier film 208 is made out of a SiCN film.

Next, as illustrated in FIG. 3K, second layered barrier film 208 is etched to form vias 209 where CoW film 205 is exposed, in order to electrically contact copper film 201 and a copper film formed later.

Next, as illustrated in FIG. 3L, a second layered copper film 210 is formed on second layered barrier film 207.

Second layered copper film 210 may also be formed to a second layered inner wiring pattern and a via pattern by repeating the manufacturing method described above with reference to FIGS. 3A to 3K for second layered copper film 210. Further, although not illustrated specifically, even after the second layered copper film, any number of layers, each of which is formed by an inner wiring pattern consisting of copper film and a via pattern, may be repeatedly formed by repeating the manufacturing method described with reference to FIGS. 3A to 3K.

According to the first example of the second exemplary embodiment, since a inner wiring pattern and a via pattern are formed in a single copper film 201, there is no process that increases the relative dielectric constant of interlayer dielectric film 206, such as, for example, forming a trench along the inner wiring pattern and the via pattern for interlayer dielectric film 206, ashing the mask material used for the forming of the recess, and cleaning after the ashing, which have been required in the damascene method. For that reason, a damaged layer does not occur in a portion of interlayer dielectric film 206 to be in contact with a side surface of copper film 201. Since the damaged layer does not occur in interlayer dielectric film 206, the increase of the relative dielectric constant of interlayer dielectric film 206 may be suppressed during the processes, and the increase of the wiring delay may be prevented to attribute the high speed operation of the semiconductor integrated circuit devices.

Further, first layered copper film 201 is metalized on substantially flat barrier film 200, and second layered copper film 209 is metalized on substantially flat barrier film 200. For that reason, in the first example of the second exemplary embodiment, it is not required to metalize first layered copper film 101 and second layered copper film 109 in a fine trench as in the damascene method, and therefore, the first example is more advantageous in further miniaturizing semiconductor integrated circuit devices.

(Second Example)

In the first example of the second exemplary embodiment, descriptions were made for an example where the primer of first layered copper film 201 is first layered barrier film 200.

The present second example is an example where the primer of the first layered film 201 is a silicon oxide film.

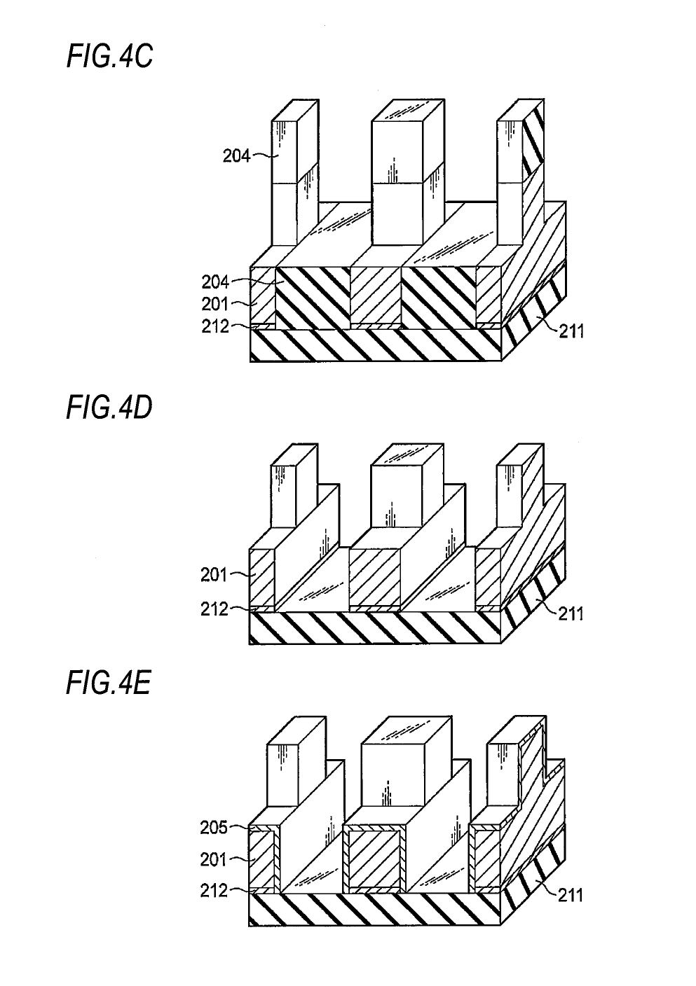

As illustrated in FIG. 4A, when the primer is a silicon oxide film 211, silicon oxide film 211 lacks a capability of suppressing the diffusion of copper. For that reason, a barrier film 212 is formed on silicon oxide film 211 using, for example, a conductively stacked film of Ta/TaN. Next, first layered copper film 201 is formed on barrier film 212. Next, a first mask material 202 is formed on first layered copper film 201 as in the first example.

Next, as illustrated in FIG. 4B, first layered copper film 201 is anisotropically etched using first mask material 202 as a mask for the etching as in the first example. Next, barrier film 212 is anisotropically etched using, for example, CF₄-based gas.

Next, as illustrated in FIG. 4C, a second mask material 204 is formed on silicon oxide film 211 and first layered copper film 201, and first layered copper film 201 is anisotropically etched using second mask material 204 as a mask for an etching, as in the first example.

Next, as illustrated in FIG. 4D, second mask material 204 is removed as in the first example. Therefore, first layered copper film 201 is processed to a first layered inner wiring pattern together with barrier film 212, and a via pattern is processed on the top side of first layered copper film 201.

Next, as illustrated in FIG. 4E, a cobalt-tungsten (CoW) film 205 is formed on first layered copper film 201 using an electroless plating method that uses a selective precipitation phenomenon.

Then, a semiconductor integrated circuit device is manufactured according to the manufacturing method described with reference to FIGS. 3H to 3L.

As in the present example, when barrier film 212 has conductivity, first layered copper films 201 may be suppressed from being shorted with each other, by patterning first layered copper film 201 along with barrier film 212.

(Third Example)

In the first example of the second exemplary embodiment, a SiCN film was used as barrier film 208 for second layered copper film 209.

In the present third example, the surface of interlayer dielectric film 206 is directly converted into a barrier layer.

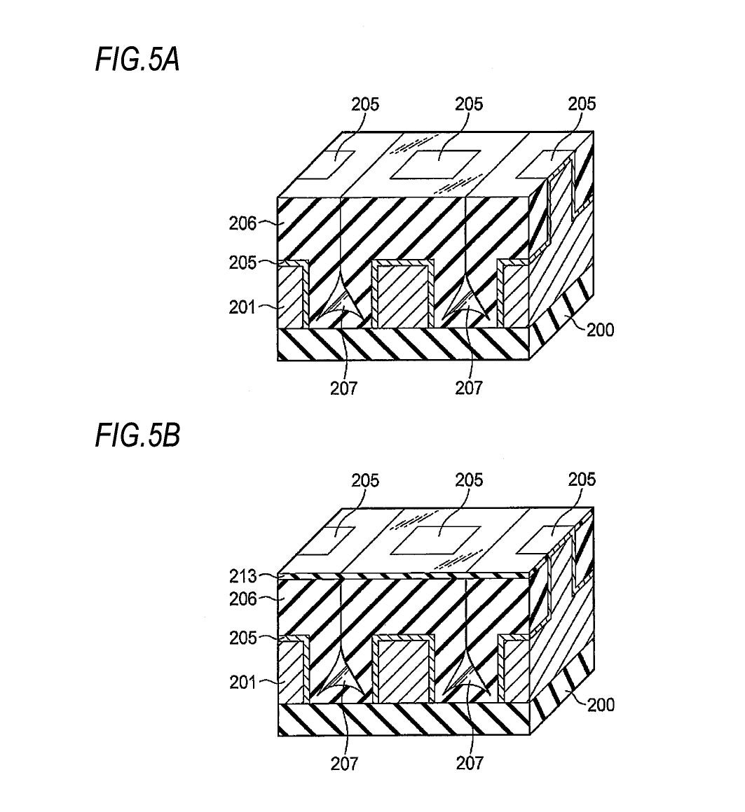

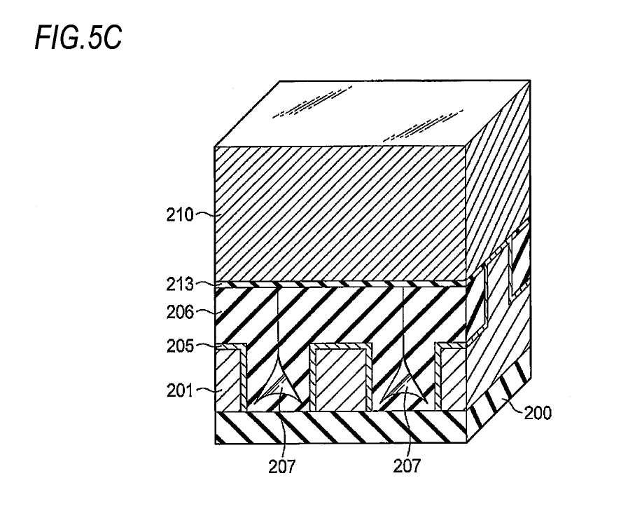

As illustrated in FIG. 5A, an interlayer dielectric film 206 is formed and the surface of interlayer dielectric film 206 retreats until a CoW film 205 or a copper film 201 is exposed, according to the manufacturing method described above with reference to FIGS. 3A to 3I.

Next, as illustrated in FIG. 5B, the surface of interlayer dielectric film 206 is nitrided using, for example, a cluster ion beam, a cluster beam, or plasma of nitrogen gas (N₂ gas). The nitrided portion is indicated by reference numeral 213. Nitrided portion 213 serves as a barrier layer that suppresses the diffusion of the copper. For that reason, as illustrated in FIG. 5C, a second layered copper film 210 may be directly formed on interlayer dielectric film 206 having nitrided portion 213.

According to the third example of the second exemplary embodiment, since the surface of interlayer dielectric film 206 is directly converted into a barrier layer, a process that forms vias in barrier film 208 may be omitted as compared with the first example of the second exemplary embodiment. For that reason, an advantage may be obtained in that the number of the manufacturing processes may be reduced in manufacturing semiconductor integrated circuit devices, thereby shortening the manufacturing time.

[Modified Example]

Although the present invention has been described above according to the exemplary embodiments, the present invention is not limited to the exemplary embodiments, and various modifications thereof may be made.

For example, the method of anisotropically etching a copper film may include three methods as described below.

A method in which a mask material is used as a mask, oxygen ions are irradiated to a copper film under an organic acid gas atmosphere, the copper film is anisotropically dry-etched until Cu barrier film is exposed or up to the midway of the copper film.)

A method in which a copper film is anisotropically etched up to a Cu barrier film or up to midway of the copper film using a mask material as a mask to form a copper oxide, and the formed copper oxide is dry-etched or wet-etched.

A method in which a process to anisotropically oxidize a surface of a copper film using a mask material as a mask and a process to dry-etch the a copper oxide formed on the surface using an organic acid gas are repeated until a Cu barrier film is exposed or up to the midway of the copper film.

An example of the organic acid gas used in the dry-etching by the organic acid gas may include a carboxylic acid containing carboxylic-group (—COOH).

As the carboxylic acid, a carboxylic acid which is expressed by formula (1) as follows may be exemplified:

R³—COOH (1)

(R³ may be selected from hydrogen, or a straight chain or branched chain type alkenyl group or alkyl group of C₁ to C₂₀)

Also, in the method (□), an wet-etching by a solution containing an organic acid or a solution containing a hydrofluoric acid may be used for the etching of the copper oxide, in addition to the dry-etching by organic acid gas.

A solution used for the wet-etching by the solution containing an organic acid may include a solution containing at least one selected from the group consisting of:

a citric acid having a carboxylic group,

an ascorbic acid having a carboxylic group,

a malonic acid having a carboxylic group, and

a malic acid having a carboxylic group.

Meanwhile, the methods (□) and (□) have an advantage in that the throughput is good and copper film 101 may be anisotropically etched, as compared with the method (□). This is because although in the method (□), a semiconductor wafer is continuously transferred between an oxidation apparatus and a dry-etching apparatus until Cu barrier film 100 is exposed, the method (□) may anisotropically etch a copper film within a single chamber and the method (□) may anisotropically etch a copper film within a single chamber and then, transfer the semiconductor wafer to another chamber to etch the copper oxide.

Accordingly, the methods (□) and (□) have a good throughput, and may anisotropically etch copper film 101 until Cu barrier film 100 is exposed, as compared with the method (□).

Description of Symbols

| | |
|---|---|
| 101: Copper film | 102: Mask material |
| 104: CoW film (plating film) | 105, 106: Interlayer dielectric film |
| 107: Space | 201: First layered copper film |
| 202: First mask material | 204: Second mask material |
| 206: Interlayer dielectric film | 209: Second layered copper film |

1. A semiconductor device manufacturing method comprising:
forming a copper film on a Cu barrier film;
forming a mask material on the copper film;
anisotropically etching the copper film using the mask material as a mask until the Cu barrier film is exposed; and
after removing the mask material, forming a plating film including a material that suppresses the diffusion of the copper on the anisotropically etched copper film using an electroless plating method using a selective precipitation phenomenon that has a catalytic action on the copper film but does not have the catalytic action on the Cu barrier film,
wherein the anisotropically oxidizing of the copper film is a process of anisotropically oxidizing the copper film to form a copper oxide up to the Cu barrier film using the mask material as a mask, and etching the copper oxide formed up to the Cu barrier film.

2. The method of claim 1, further comprising forming an interlayer dielectric film around the copper film which is formed with the plating film thereon.

3. (canceled)

4. The method of claim 1, wherein the plating film is an alloy made of cobalt containing at least a tungsten.

5. The method of claim 1, wherein the anisotropically etching the copper film is a process of irradiating oxygen ions to the copper film under an organic acid gas atmosphere using the mask material as a mask, and anisotropically etching the copper film until the Cu barrier film is exposed, and
the organic acid gas contains a carboxylic acid having a carboxylic group.

6-7. (canceled)

8. A semiconductor device manufacturing method comprising:
forming a copper film on a Cu barrier film;
forming mask materials to be spaced apart from each other on the copper film;
anisotropically etching the copper film using the mask materials as a mask until the Cu barrier film is exposed; and
after removing the mask materials, forming an interlayer dielectric film having a space between the anisotropically etched copper films by depositing an insulation material on the anisotropically etched copper film to be pinched-off on the top of the copper film.

9. The method of claim 8, further comprising: between the removing of the mask materials and forming of the interlayer dielectric film,
forming a plating film containing a material that suppresses the diffusion of the copper on the anisotropically etched copper film using an electroless plating method that uses a selective precipitation phenomenon that has a catalytic action on the copper film but does not have the catalytic action on the Cu barrier film.

10. (canceled)

11. The method of claim 8, wherein the anisotropically etching the copper film is a process of irradiating oxygen ions to the copper film under an organic acid gas atmosphere using the mask material as a mask, and anistropically etching the copper film until the Cu barrier film is exposed.

12. The method of claim 11, wherein the organic acid gas contains a carboxylic acid having a carboxylic group.

13. The method of claim 8, wherein the anisotropically etching the copper film is a process of anisotropically oxidizing the copper film to form a copper oxide up to the Cu barrier film using the mask materials as a mask, and etching the copper oxide formed up to the Cu barrier film.

14-15. (canceled)

16. The method of claim 13, wherein a dry-etching by an organic acid gas is used for the etching of the copper oxide and the organic acid gas contains a carboxylic acid having a carboxylic group.

17-18. (canceled)

19. A method for manufacturing a semiconductor device comprising:
(1) forming a copper film on a barrier film;
(2) forming a first mask material on the copper film;
(3) anisotropically etching the copper film using the first mask materials as a mask until the barrier film is exposed;
(4) after removing the first mask material, forming a second mask material on the anisotropically etched copper film;
(5) anisotropically etching the copper film using the second mask material as a mask up to the midway of the copper film; and
(6) after removing the second mask material, forming an interlayer dielectric film around the anisotropically etched copper film by depositing insulating material on the anistropically etched copper film.

20. The method of claim 19, wherein a wiring pattern is processed on the copper film at the step (3), and
a via pattern is processed in the copper film to electrically connect an upper layer wiring and a lower layer wiring at the step (5).

21. The method of claim 19, further comprising: until the interlayer dielectric film is formed after removing the second mask material at the step (6),
(7) forming a plating film containing a material that suppresses the diffusion of the copper on the anisotropically etched copper film using an electroless plating method that uses a selective precipitation phenomenon which has a catalytic action on the copper film but does not have the catalytic action on the barrier film.

22. The method of claim 21, wherein the plating film is an alloy made of cobalt containing at least tungsten.

23. The method of claim 19, further comprising: after the step (6),
(8) retreating the surface of the interlayer dielectric film until the plating film or the copper film is exposed,.
wherein the step (8) is performed by a mechanical and chemical polishing method, and the end point of the mechanical and chemical polishing is sensed by detecting a change of a current that flows through a motor of a mechanical and chemical polishing apparatus.

24. (canceled)

25. The method of claim 23, further comprising: after the step (8),
(9) converting the surface of the interlayer dielectric film into a barrier layer that suppresses the diffusion of copper.

26. The method of claim 25, wherein the step (9) is a process that nitrides the surface of the interlayer dielectric film.

27. The method of claim 19, wherein the step (3) is a process that anisotropically etches the copper film until the barrier film is exposed using the first mask material as a mask, and irradiating oxygen ions to the copper film under an organic acid gas atmosphere, and
the (5) step is a process that anisotropically etches the copper film up to the midway of the copper film using the second mask material as a mask, and irradiating oxygen ions to the copper film under an organic acid gas atmosphere.

28. The method of claim 27, wherein the organic acid gas contains a carboxylic acid having a carboxylic group.

29. The method of claim 28, wherein the carboxylic acid is expressed by formula (1) as follows:
R³—COOH (1)
(R³ is hydrogen, or a straight chain or branched chain type alkyl group or alkenyl group of C₁ to C₂₀)

30. The method of claim 19, wherein the step (3) is a process of anisotropically oxidizing the copper film to form a copper oxide up to the barrier film using the first mask material as a mask, and etching the copper oxide formed up to the barrier film, and
the step (5) is a process of anisotropically oxidizing the copper film to form a copper oxide up to the midway of the copper film using the second mask material as a mask, and etching the copper oxide formed up to the midway of the copper film.

31-32. (canceled)

33. The method of claim 30, wherein in the etching of the copper oxide, a dry-etching by an organic acid gas is used.

34. The method of claim 33, wherein the organic acid gas contains a carboxylic acid having a carboxylic group.

35. The method of claim 34, wherein the carboxylic acid is expressed by formula (1) as follows:
R³—COOH (1)
(R³ is hydrogen, or a straight chain or branched chain type alkenyl group or alkyl group of C₁ to C₂₀)
